(19) United States
(12) Patent Application Publication
(10) Pub. No.: US 2013/0167910 A1
(43) Pub. Date: Jul. 4, 2013

(54) PHOTOVOLTAIC CELL ASSEMBLY AND METHOD

(71) Applicants: Marty W. DeGroot, Midland, MI (US); Michael E. Mills, Midland, MI (US); Thomas J. Parsons, Freeland, MI (US); Narayan Ramesh, Midland, MI (US); Matt Stempki, Midland, MI (US); Douglas J. Wirsing, Midland, MI (US)

(72) Inventors: Marty W. DeGroot, Midland, MI (US); Michael E. Mills, Midland, MI (US); Thomas J. Parsons, Freeland, MI (US); Narayan Ramesh, Midland, MI (US); Matt Stempki, Midland, MI (US); Douglas J. Wirsing, Midland, MI (US)

(73) Assignee: DOW GLOBAL TECHNOLOGIES LLC, Midland, MI (US)

(21) Appl. No.: 13/820,647

(22) PCT Filed: Sep. 14, 2011
(86) PCT No.: PCT/US2011/051509

§ 371 Date: Mar. 4, 2013

Related U.S. Application Data
(60) Provisional application No. 61/383,867, filed on Sep. 17, 2010.

(51) Int. Cl. H01L 31/05

(52) U.S. Cl. CPC H01L 31/0504
USPC 136/251; 438/67

(57) ABSTRACT

The present invention provides an improved photovoltaic cell assembly (10) that includes at least plurality of photovoltaic calls (20). The cells include a photoactive portion (24) sandwiched between a top electrically conductive structure (28) on some regions of a top surface (28) of the photoactive portion leaving exposed top surface on other regions; and an opposing conductive substrate layer (22). The improved photovoltaic cell assembly also includes a plurality of conductive elements (80); a first encapsulant layer (40) In contact with the top electrically conductive structure and the exposed fop surface of the photoactive portion; and a second encapsulant layer (50) in contact with the opposing conductive substrate layer, the encapsulants holding the conductive elements to the cell layers.

### CLAIM OF PRIORITY

The present application claims the benefit of the filing date of U.S. Provisional Application No. 61/383,867 (filed 17-Sep.-2010) the contents of which are hereby incorporated by reference in their entirety.

### FIELD OF THE INVENTION

The present invention relates to an improved photovoltaic (PV) cell assembly, more particularly to an improved photovoltaic cell assembly that interconnects a plurality of cells without solder or conductive adhesive.

### BACKGROUND

Photovoltaic articles often comprise a number of electrically interconnected photovoltaic cells. In addition to ensuring electrical interconnection, these cells are sometimes packaged to protect the cells from damage from handling or the environment. The conventional approach to electrical interconnection of photovoltaic cells is the so-called string & tab method, in which solar cells are connected to each other using tin or solder coated flat wire (bus) ribbons and bonded by soldering and/or other adhesive material such as conductive epoxy. The wire ribbon is typically bonded to bus bar locations on a conductive grid that is applied to the surface of the cell. It is believed that the cross section of the wire may be limited such that thicker wires are too stiff and thin and wide wires obscure too much light. The net result is that interconnect resistance losses as well as the amount of active cell surface area that is blocked by the ribbon can account for significant reduction in photovoltaic cell assembly (hence the PV device) performance. The stringing process may also be difficult to use with thin cells because the resulting series string of cells may be fragile and susceptible to lost contact of the PV ribbon with the solar cell. Furthermore, the appearance of the large bus ribbons on the surface of the PV device may be aesthetically undesirable to customers.

Among the literature that can pertain to this technology include the following patent documents: U.S. Pat. No. 6,936,761; U.S. Pat. No. 7,022,910; U.S. Pat. No. 7,432,438; U.S. Publications 2007/0251570; 2009/00025788; and 2009/0255565, all incorporated herein by reference for all purposes.

### SUMMARY OF THE INVENTION

The present invention is directed to an improved photovoltaic cell assembly that addresses at least one or more of the issues described in the above paragraphs.

It is believed that one potential benefit of the present invention over the prior art is that the inventive photovoltaic cell assembly is constructed and configured in such a way that conductive adhesive and/or solder is not required to hold the cell strings together. It is contemplated that the cell string is encapsulated in a polymer laminate during or immediately following the application of conductive wires. The elimination of conductive adhesive may be desirous, because conductive adhesive can be expensive and requires substantial down time for maintenance and cleaning. A further advantage contemplated may be improved resistance to thermal cycling and damp heat treatment over adhesive or soldered connections that may be susceptible to degradation under these types of environmental stresses. The photovoltaic cell assembly described herein also lacks large bus ribbons that obstruct light from entering the cell. The absence of the bus ribbons also may render the PV device aesthetically more appealing versus conventional products prepared using the string and tab approach. Furthermore, the use of this approach may reduce the amount of silver conductive ink in grid application via elimination of large silver bus bars that are generally applied for photovoltaic cell assemblies prepared using string and tab approach. A further unexpected advantage of this approach may be that solar cell strings (e.g. multiple cells, for example a 5-cell assembly/string) assembled using the present invention may repeatedly exhibit higher efficiency and current generated and lower series resistance relative to the individual cells used in their production because the addition of a conductive element lowers resistance relative to the individual cells that do not have the conductive element. In contrast, as seen in the experimental example discussed later in the specification, 5-cell strings connected with flat wire ribbon and conductive epoxy have demonstrated the opposite tendency, with lower efficiency and current and higher series resistance relative to the individual component cells.

Accordingly, pursuant to one aspect of the present invention, there is contemplated a photovoltaic cell assembly including at least a plurality of photovoltaic cells, the cells including at least: a photoactive portion sandwiched between; a top electrically conductive structure on some regions of a top surface of the photoactive portion leaving exposed top surface on other regions; and an opposing conductive substrate layer; wherein at least a portion of a peripheral edge portion of the cells include a non-conductive layer portion; a plurality of conductive elements; a first encapsulant layer in contact with the top electrically conductive structure and the exposed top surface of the photoactive portion; and a second encapsulant layer in contact with the opposing conductive substrate layer; wherein one end of the plurality of conductive elements contact the top electrically conductive structure and the exposed top surface and an opposing end of the plurality of conductive elements contact the conductive substrate layer of an adjacent photovoltaic cell and both ends are held in contact to the cell layers by the respective encapsulant layer.

The invention may be further characterized by one or any combination of the features described herein, such as the collection structure comprises a series of substantially parallel fines of a material with lower sheet resistance than the exposed top surface; the series of substantially parallel lines is generally perpendicular to the direction of the plurality of conductive elements; the number of conductive elements and the cross section width of the conductive elements is selected so that a total power loss due to line resistance of the conductive elements and the shading of the conductive elements is less than 6% according to the equation:

$$\begin{matrix}Total power loss = [ power loss due to shading ] + \\ [ power loss due to resistive line losses ] \\ = [ \{ ρ ( l \text{/} n ) ( / ) \} \text{/} ( V ) ( A ) ] + [ n ( {/}^{′} ) ( d ) ]\end{matrix}$$

where ρ is the resistivity of the conductive element, I is the current generated by the PV device, n is the number of conductive elements, l is the length of the conductive elements, V is the voltage generated by the PV device, A is the cross sectional area of the conductive elements, l′ is the length of the conductive element that covers the top surface of the PV cell and d is the diameter of the conductive element; a total surface area of the collection structure and the plurality of conductive elements is less than 4% of the total surface area of the PV cells; the power loss contributed by shading is between 30-70% of the total power loss caused by shading and resistive losses; the cross section width of the conductive elements is greater than the thickness of the first and second encapsulant layer; a cross section width of the conductive elements is less than 0.5 mm and greater than 0.1 mm; the conductive elements are connected to terminal bars at both ends of the assembly; the conductive elements are connected to the terminal bars via soldering or welding; the conductive elements are connected to terminal bars via laser welding; the first encapsulant layer and the second encapsulant layer comprise multiple layers, wherein the first layer proximal to the top and bottom cell surfaces is a thermoplastic material with a higher melting point than the subsequent layers; the top surface comprises a transparent conductive oxide; the photovoltaic cell assembly comprises at least five photovoltaic cells and at least three conductive elements; the photovoltaic cell assembly comprises at least ten conductive elements; an overlap of the conductive elements on the conductive substrate layer is at least 2.0 mm in length; the non-conductive layer portion comprises a liquid dielectric that is cured via UV radiation; the first encapsulant layer, the second encapsulant layer, or both comprise at least a first and a second layer, wherein the first layer has a higher melting temperature (Tₘ) than the second layer; a difference in melting temperature (Tm) is at least 10° C.

Accordingly, pursuant to another aspect of the present invention, there is contemplated a method of forming a photovoltaic assembly including at least the steps of: providing a first encapsulant layer and a second encapsulant layer; providing a series of substantially parallel conductive elements; providing a plurality of photovoltaic cells comprising a photoactive layer, an opposing conductive substrate layer and a top conductive layer comprising both a transparent conductive layer and a collection structure; connecting the plurality of photovoltaic cells in top-to-bottom fashion; the collection structure comprises a series of substantially parallel lines and a peripheral edge portion of the cells include a non-conductive layer portion and one end of the plurality of conductive elements contact both the transparent conductive layer and the collection structure and an opposing end of the plurality of conductive elements contact the conductive substrate layer of an adjacent photovoltaic cell and both ends are held in contact to the cell layers by the respective encapsulant layer

It should be appreciated that the above referenced aspects and examples are non-limiting, as others exist within the present invention, as shown and described herein.

### DESCRIPTION OF THE DRAWINGS

FIG. 1 is a top perspective view of one illustrative example of the present invention.

FIG. 2 is a side view of the example shown in FIG. 1.

FIG. 3 is an exploded side view of the example shown in FIG. 1.

FIG. 4 is a more detailed side view of the example shown in FIG. 1.

FIG. 5 is a top perspective view of a single cell.

FIG. 5 A-A is a detailed sectional view of the cell of FIG. 5, illustrating example layers.

FIG. 6 is a top perspective view of a PV device with a 4-cell photovoltaic cell assembly included therein.

FIG. 7 is a top perspective view of according to Example 1.

FIG. 8 is a top perspective view of according to Example 2.

FIG. 9 is a top perspective view of according to Examples 3 and 4.

FIG. 10 is a top perspective view of according to Example 5.

FIG. 11 is a graphical example of the effect of wire resistivity on the series resistance and normalized efficiency of cell assemblies, related to Example 5.

FIG. 12 is a graphical example showing an example of how power loss (normalized efficiency) can be minimized experimentally by optimization of the number of conductive elements.

FIG. 13 is a table related to Example 1.

FIG. 14 is a table related to Example 3.

FIG. 15 is a table related to Example 4.

FIG. 16 is a table related to Examples 6 and 7.

FIGS. 17A-C illustrates I-V exemplary characterization data for the individual cells and the interconnected assembly.

### DETAILED DESCRIPTION OF THE PREFERRED EMBODIMENT

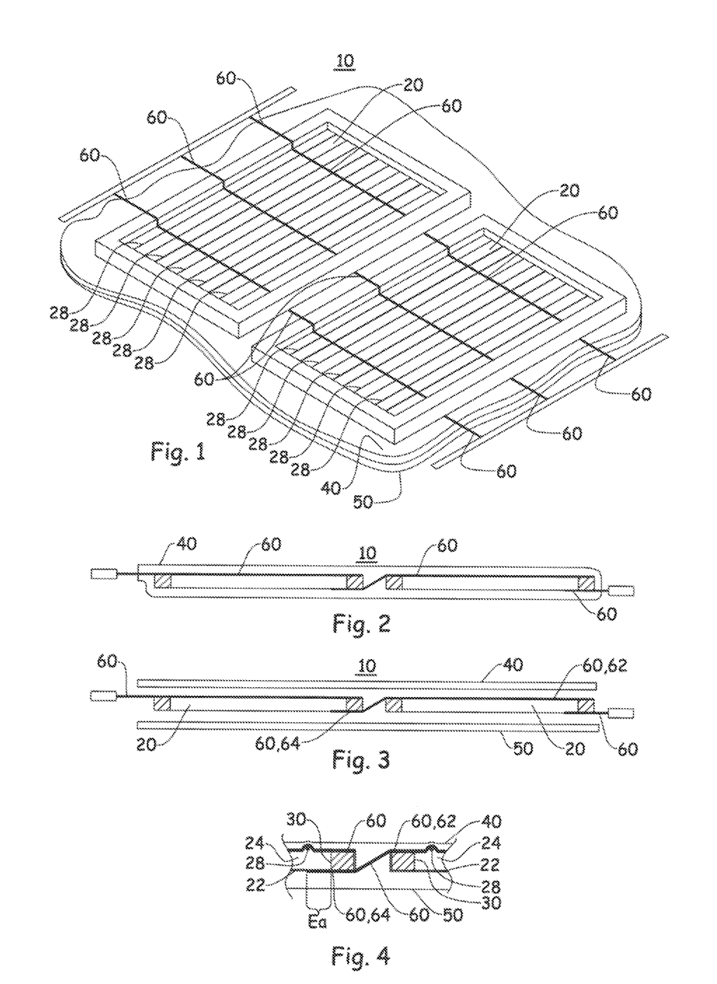

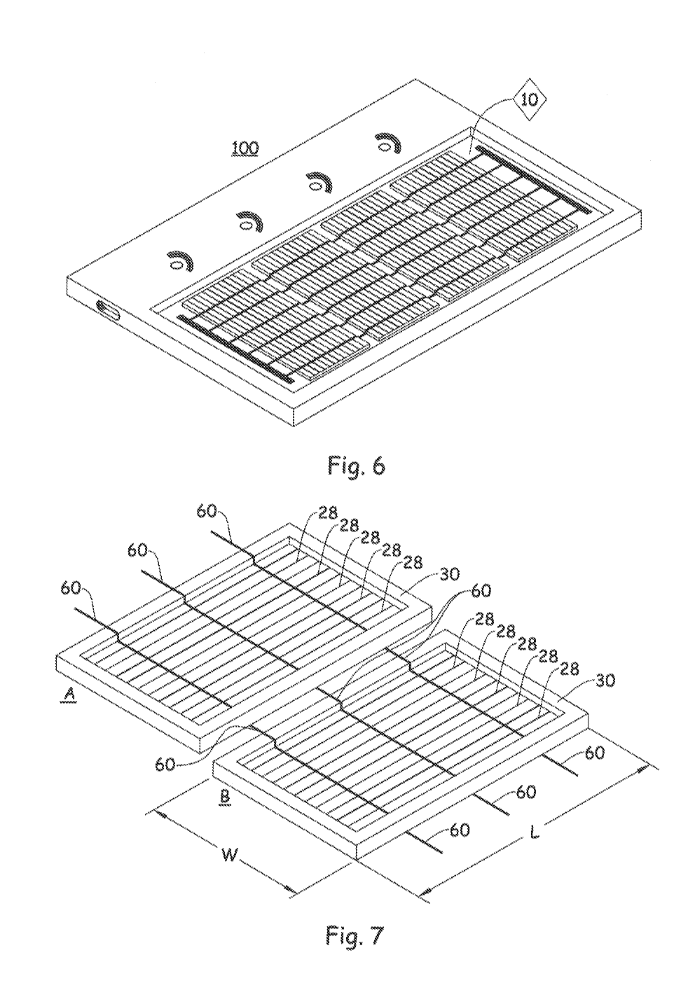

The present invention relates to an improved photovoltaic cell assembly 10, as illustrated in FIGS. 1-5A-A and 7-10, and can be described generally as an assembly of a number of components and component assemblies that functions to provide electrical energy when subjected to solar radiation (e.g. sunlight). In one example, the improved photovoltaic cell assembly 10 may be incorporated into a larger photovoltaic device, for example a solar shingle 100 as shown in FIG. 6.

Of particular interest and the main focus of the present disclosure is an improved photovoltaic cell assembly 10 that includes at least a plurality of photovoltaic cells 20, first and second encapsulant layers 40, 50, and a conductive element 60 (preferably a plurality of conductive elements 60) that electrically connects the photovoltaic cells 20.

Generally, the plurality of photovoltaic cells may be constructed of a plurality adjoining of layers. These layers can be further defined (e.g. from the bottom up) to include at least: a conductive substrate layer 22; a photoactive layer 24; and a top electrical collection structure 28. It is also preferred that at least along a portion of the peripheral edge of the cells a non-conductive layer portion 30 is included, for example as illustrated in FIG. 4.

Furthermore, the assembly 10 is configured such that one end 62 of the conductive element 60 is in contact with both the collection structure 28 and a top surface 26 of the photoactive layer 24 and an opposing end 64 of the conductive element 60 is in contact with the conductive substrate layer 22 of an adjacent photovoltaic cell 20. Preferably, both ends 62, 64 are held in contact to the cell layers by the respective encapsulant layer.

It is contemplated that the relationships (e.g. at least the geometric properties and the material properties) between the components and component assemblies are surprisingly important in solving one or more the issues discussed in the background section above. Each of the components and component assemblies and their relationships are disclosed in greater detail and specificity in the following paragraphs.

The photovoltaic cell 20 contemplated in the present invention may be constructed of any number of known photovoltaic cells commercially available or may be selected from some future developed photovoltaic cells.

### Conductive Substrate Layer 22

The conductive substrate layer 22 functions similarly to the top conductive layer 24, in mat it conducts the electrical energy produced by the photoactive portion. The conductive substrate layer 22 may be rigid or flexible, but desirably is flexible, particularly in those embodiments in which the resultant photovoltaic device may be used in combination with non-flat surfaces. The conductive substrate layer can be a single integral layer or can be formed from one or more layers formed from a wide range of materials, including metals, metal alloys, intermetallic compositions, and/or combinations of these. For applications wherein a flexible substrate layer is desired, layer 22 is typically a metal foil. Examples include metal foil comprising Cu, Ai, Ti, Mo or stainless steel. Typically, this conductive substrate layer is formed of a stainless steel and the photoactive portion 24 is formed above the substrate layer, although other configurations are contemplated and do not necessarily effect the concepts of cell interconnect presented herein. In illustrative embodiments, stainless steel is preferred.

The conductive substrate layer 22 can be coated on one or both sides with a wide range of electrically conductive materials, including one or more of Cu, Mo, Ag, Al, Cr, Ni, Ti, Ta, Nb, W and/or combinations of these. Conductive compositions incorporating Mo may be used in an illustrative embodiment. A back contact layer 122 formed on the conductive substrate layer proximal to the photoactive layer helps to isolate the photoactive layer 24 from the support to minimize migration of support constituents into the photoactive layer. For example, the hack contact layer 22 can help to block the migration of Fe and Ni constituents of a stainless steel support into the photoactive layer 24. Conductive metal layers formed on one or both sides of the conductive substrate layer 22 can also can protect the substrate layer against degradation that could be caused during formation of the photoactive layer 24, for instance by protecting against S or Se if these are used in the formation of photoactive region 24.

### Photoactive Portion 24

The photoactive layer or portion 24 of the photovoltaic cell 20 contains the material which converts light energy to electrical energy. Any material known to provide that function may be used including crystalline silicon, amorphous silicon, CdTe, GaAs, dye-sensitized solar cells (so-called Graetzel cells), organic/polymer solar cells, or any other material that converts sunlight into electricity via the photoelectric effect. However, the photoactive cell is preferably a IB-IIIA-chalcogenide-based cell, such as IB-IIIA-selenides, IB-IIIA-sulfidas, or IB-IIIA-seienide sulfides (i.e. absorber layer is a IB-IIIA chalcogenide, preferably a copper chalcogenide). More specific examples include copper indium selenides, copper indium gallium selenides, copper gallium selenides, copper indium sulfides, copper indium gallium sulfides, copper gallium selenides, copper indium sulfide selenides, copper gallium sulfide selenides, and copper indium gallium sulfide selenides (all of which are referred to herein as CIGS). These can also be represented by the formula CuIn₍₁₋ₓ₍GaₓSe_{(2-y)}S_{y} where x is 0 to 1 and y is 0 to 2. The copper indium selenides and copper indium gallium selenides are preferred. The portion 24 may comprise multiple layers in addition to the absorber layer such as one or more of emitter (buffer) layers, conductive layers (e.g. transparent conductive layers) and the like as is known in the art to be useful in CIGS based cells are also contemplated herein. These cells may be flexible or rigid and come in a variety of shapes and sizes, but generally are, fragile and subject to environmental degradation. In a preferred embodiment, the photovoltaic cell 20 is a cell that can bend without substantial cracking and/or without significant loss of functionality. Exemplary photovoltaic cells are taught and described in a number of US patents and publications, including U.S. Pat. No. 3,767,471, U.S. Pat. No. 4,465,575. US20050011550 A1, EP841706 A2, US20070256734 at, EP1032051A2, JP2218874, JP2143468, and JP10189924a, incorporated hereto by reference for all purposes.

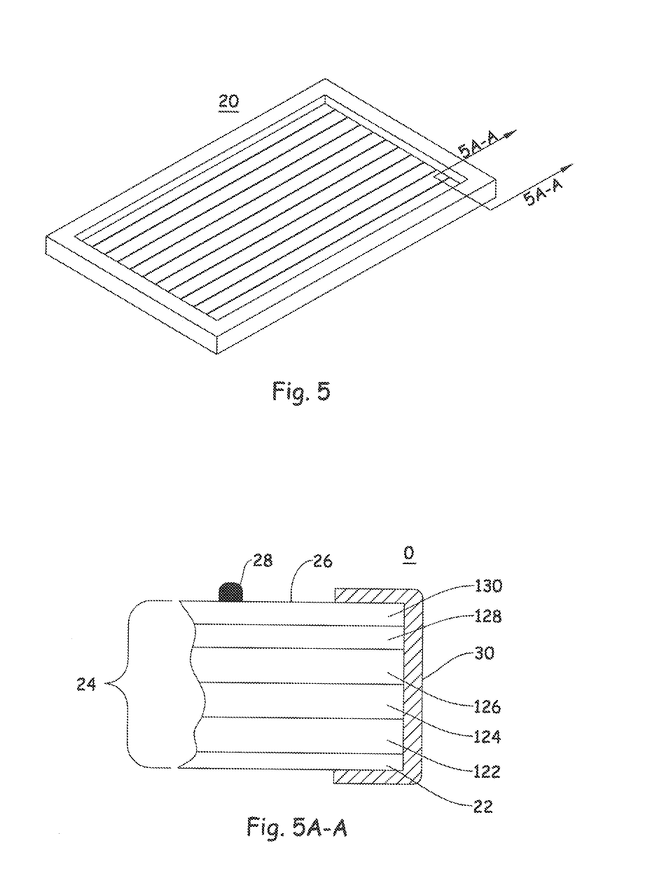

In a exemplary embodiment, the photoactive layer 24 may be further constructed of any number of layers, for example: a back contact layer 122 (typically Mo); an absorber layer 124 (typically CuInGaSe(S)); a buffer layer 126 (typically CdS); a window layer 128 (typically ZnO); and transparent conductive layer 130 (typically indium tin oxide (ITO or aluminum zinc oxide (AZO)). If is believed that cells 20 of this configuration are typically known as “CIGS solar cells”, see FIG. 5A-A.

It is contemplated that the photovoltaic cells 20 may be formed from other known solar cell technology. Examples of these include amorphous silicon or cadmium telluride based solar cell devices. Additionally, components within the photovoltaic cells 20 as described above can be substituted for alternative materials. For example, the buffer layer 126 can be for sulfides, selenides or oxides of Cd, Zn, In, Sn and combinations thereof; An optional window layer compromised of a resistance transparent oxide of for example Zn, Cd, In, Sn may be included between the buffer region 126 and the transparent conductive layer 130. Preferably, the window layer is intrinsic zinc oxide.

The transparent conductive layer 130 may be situated as the top layer of the photoactive layer 24. A wide variety of transparent conducting oxides or combinations of these may be incorporated into the transparent conductive layer. In typical embodiments, the transparent conductive layer 130 is a transparent conductive oxide (TCO), with representative examples including fluorine-doped tin oxide, tin oxide, indium oxide, indium tin oxide (ITO), aluminum doped zinc oxide (AZO), zinc oxide, combinations of these, and the like, in one illustrative embodiment, the transparent conductive layer is indium tin oxide. Transparent conductive layers may be conveniently formed via sputtering or other suitable deposition technique.

It is contemplated that in certain photovoltaic cells 20, a distinctive transparent conductive layer 130 may not be required. For example GaAs type cells typically do not require a transparent conductor as the GaAs layer may be sufficiently conductive. For the sake of the present invention, then the layer that is immediately below the collection structure 28 should be considered the top surface 26 of the cell 20.

These substitutions are known to those in the art and does not affect the concept of cell interconnect presented herein.

### Top Collection Structure 28

The top collection structure 28 functions to collect the electrical energy produced by the photoactive portion 22 and focus it into conductive paths. The collection structure 28 may be deposited over the photoactive layer 24 (e.g. on the fop surface 26) to reduce the sheet resistance of this layer (e.g. TCO layer 130). The collection structure 28 typically comprises optically opaque materials and may be applied as a series of substantially parallel conductive traces (although other configurations are contemplated and do not necessarily effect the concept of cell interconnect presented herein) with spaces between the traces so that the grid occupies a relatively small footprint on the surface. For example, in some embodiments, the collection structure occupies about 5% or less, even about 2% or less, or even about 1% or less of the total surface area associated with light capture to allow the photoactive materials to be exposed to incident light. The collection structure 28 preferably includes conductive metals such as Ag, Al, Cu, Cr, Ni, Ti, Ta, and/or combinations thereof. In one illustrative embodiment, the grid has a dual layer construction comprising nickel and silver. The collection structure can be formed by a variety of techniques including screen-printing, ink-jet printing, electroplating, and metallization through a shadow mask using physical vapor deposition techniques such as evaporation or sputtering.

### Non-Conductive Layer Portion 30

The non-conductive layer portion 30 functions as an insulator or a dielectric that electrically isolates the conductive elements 60 from the edges of the solar cells. It is contemplated that the presence of the non-conductive layer portion reduces the occurrence of electrical shorts at the edge of the solar cell that may be caused by contact with the conductive elements 60. Furthermore, the non-conductive layer portion 30 can function as an adhesive to secure the plurality of conductive elements 60 in place during fabrication of the cell assembly prior to application of the encapsulant layers. The insulator can be applied to the solar cell or to the conductive elements 60 at one or both of the leading or trailing edges of each individual solar cell in the solar cell assembly. The insulator can be formed as discrete regions along the edge of the device at the locations where the conductive elements cross the edge of the solar cell, or it can be applied as a single layer along the entire length or a substantial portion of the edge of the cell 20, so that it may comprise a discrete layer between the cell and the conductive elements 60. The insulator may be of a type of synthetic polymer that can be deposited as a liquid and cured or cross-linked to form a solid material. Curing or cross-linking can be achieved via the application of thermal or ultraviolet (UV) energy, for example. For UV-curable compositions, it is desirable that the curing process can be carried out in a short timeframe, such as less than 10 seconds, and more specifically can be less than about 3 seconds. Many photocurable polymers require energy of at least 300 mJ/cm² and more typically about 500-1200 mJ/cm² of UV energy in the 200-400 nm range. Exemplary embodiments include acrylate and epoxy resin based compositions. Alternatively, the non-conductive layer portion 30 can be applied as a solid material, such as in tape form. Suitable alternatives may include fluorocarbon polymers, such as ethylene tetrafluoroethylene (ETFE), curable insulating polymers that can be coated on the cell or interconnect material or inorganic dielectric material that can be applied to the solar cell or interconnect material. It is contemplated that it could also be substituted for the material used as the encapsulant layers 40, 50, such as polyethylene film, in a preferred embodiment, the non-conductive layer portion 30 is a liquid dielectric epoxy composition that is cured via UV radiation. In one illustrative embodiment, the portion 30 is a polyimide tape. One such commercially available tape is Kapton® tape offered by Dupont®. In general, the non-conductive layer portion 30 can exhibit a dielectric constant greater than about 2 and can be even greater than about 4. Exemplary electrically insulating materials have a dielectric constant greater than about 4.8 and volume resistivity greater than about 3×10¹⁴ Ω-cm.

### Conductive Elements 60

The conductive element(s) 60 function as an electrical bridge between photovoltaic cells 20. It is contemplated in the present invention that, the electrical bridge is formed between the top of one cell (e.g. collection structure 28 and/or top surface 26) and the conductive substrate layer 26 of an adjoining cell. It is desirable that these elements have a relatively low electrical resistance (preferably less than about 1.0 Ω/m, more preferably less than about 0.33 Ω/m, most preferably less than 0.15 Ω/m). FIG. 11 shows an example of the effect of wire resistivity on the series resistance and normalized efficiency of cell assemblies. They may be in the form of traditional metallic wires (solid or plated), conductive foils, coated polymeric strands, or any like structure that performs the above bridging function. Illustrative conductive elements include copper wires plated with Ag, Sn or Ni. The elements 60 are free of alloys with a relatively low melting point (e.g. a melting point lower than the desired processing temperature of the cell assembly, typically less than about 200° C.), solder, or conductive adhesive components.

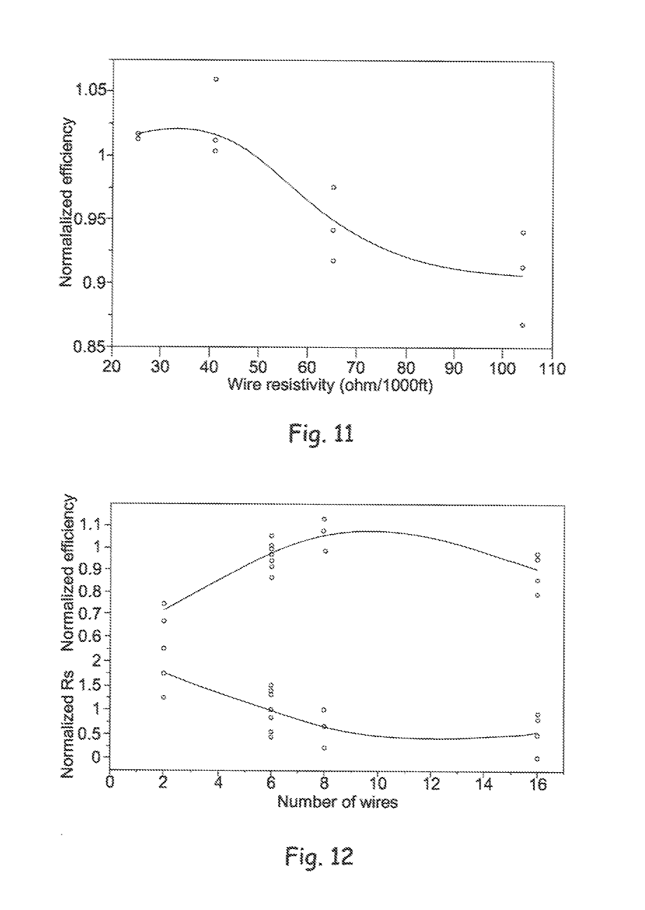

It is contemplated that the number of conductive elements 60 used per individual cell may vary from as little as two (2) (e.g. one on top and one on the bottom) to as many as several dozen. The number of and relative spacing of the conductive elements 60 may vary based upon a number of factors, such as: the type and resistivity of the of the elements; the size of the cell 20; the type, resistivity and spacing of the lines in the collection structure 28, the sheet resistance of the top surface 26; spacing of individual elements of the collection structure 28; and the contact resistance of all relevant interfaces (e.g. collection structure/fop surface, collection structure/conductive elements, top surface/conductive elements). These values can each be measured and used to determine preferred configurations in order to minimize total power loss and to balance the contributions to power loss associated with shading due to the conductive elements and the collection structure, and the contribution associated with resistance losses from the relevant interfaces. In a preferred embodiment, there are four (4) conductive elements 60 per 100 cm² of cell 20 surface and these are approximately spaced apart about evenly (e.g. the spacing value within about 5 to 25% of each other). FIG. 12 shows an example of how power loss (normalized efficiency) can be minimized experimentally by optimization of the number of conductive elements.

It is contemplated that there should be sufficient contact between the elements 60 and the conductive substrate layer 22 to meet the resistivity goals (e.g. less than about 1.0Ω, more preferably less than about 0.2Ω). It is envisaged that the overlap “C_{A}” of the elements 60 on the conductive substrate layer 22 (see FIG. 4) may range from as little as about 2.0 mm to as much as the entire width “W” of the cell. In a preferred embodiment, the overlap “C_{A}” ranges from about 2.0 mm to 100.0 mm, more preferably from about 5.0 mm to 80.0 mm, and most preferably from about 20.0 mm to 50.0 mm.

It is contemplated that the number of conductive elements and the cross section width of the conductive elements may be selected so that the total power loss due to line resistance of the conductive elements and the shading of the conductive elements is less than about 3% to 6% according to the equation:

$$\begin{matrix}Total power loss = [ power loss due to shading ] + \\ [ power loss due to resistive line losses ] \\ = [ \{ ρ ( l \text{/} n ) ( / ) \} \text{/} ( V ) ( A ) ] + [ n ( {/}^{′} ) ( d ) ]\end{matrix}$$

where ρ is the resistivity of the conductive element, I is the current generated by the PV device, n is the number of conductive elements, l is the length of the conductive elements, V is the voltage generated by the PV device, A is the cross sectional area of the conductive elements, l′ is the length of the conductive element that covers the top surface of the PV cell and d is the diameter of the conductive element

In a preferred embodiment, the cross section width of the conductive elements may range from about 0.1 mm to 2.0 mm, more preferably from about 0.2 mm to 1.0 mm, and most preferably from about 0.3 mm to 0.5 mm. In a preferred embodiment, the power loss contributed by shading may be between about 25-75% of the total power loss caused by shading and resistive losses, more preferably between about 30-70%.

### First Encapsulant Layer 40

It is contemplated that the first encapsulant layer 40 may perform several functions. For example, the layer 40 may serve as a bonding mechanism, helping hold the adjacent layers together (e.g. the cell 20; the plurality of conductive elements 60; and/or the second encapsulant layer 50). It should also allow the transmission of a desirous amount and type of light energy to reach the photovoltaic cell 20 (e.g. the photoactive portion 24). The first encapsulant layer 40 may also function to compensate for irregularities in geometry of the adjoining layers or translated though those layers (e.g. thickness changes). It also may serve to allow flexure and movement between layers due to environmental factors (e.g. temperature change, humidity, etc.) and physical movement and bending. Preferably, the layer 40 is configured to keep the plurality of conductive elements 60 in electrical contact with the top surface 26 and the collection structure 28. In a preferred embodiment, first encapsulant layer 40 may consist essentially of an adhesive film or mesh, but is preferably a thermoplastic material such as EVA (ethylene-vinyl-acetate), thermoplastic polyolefin or similar material. It is contemplated that the layer 40 may be comprised of a single layer or may be comprised of multiple layers (e.g. a first, second, third, fourth, fifth layer, etc.). In the case that layer 40 is comprised of multiple layers, it is contemplated that the first layer formed proximal to the top surface of the cell (e.g. in contact with the fop surface 26, the top electrical collection structure 28 and the conductive elements 60) has a higher melting temperature (Tₘ) than a second layer formed proximal to the first layer. If is contemplated that this configuration can provide the advantage that a processing temperature can be selected such that the first layer does not completely melt during heat treatment, but reaches sufficient temperature to cause adhesion of the first layer to the top of the cell. This configuration prevents loss of contact of the conductive elements with the top conductive layer due to underflow of the encapsulant material between the conductive elements and the top conductive layer during heat treatment. The preferred thickness of this layer 40 can range from about 0.1 mm to 1.0 mm, more preferably from about 0.2 mm to 0.8 mm, and most preferably from about 0.25 mm to 0.5 mm. For a multilayer configuration, it is conceived that layer 40 should be comprised of different layers in which the difference in melting temperature (Tₘ) is at least 10° C. The processing temperature should be selected to be about 5° C. or more less than the Tₘ of the first layer and at least 5° C. greater than the Tₘ of the second layer. By way of example, one such combination could be a first layer comprising of a polyolefin thermoplastic material with a melt temperature in the range of 105-130° C. and a second layer comprising of an EVA copolymer type with a nominal melt temperature of 50-100° C.

It is contemplated that “good” adhesion via adsorption of the encapsulant layers to all surfaces being contacted is important to maintaining the integrity of the encapsulated assembly. As a general guide, adhesion forces measured for adsorption to glass should be greater than about 20 N/15 mm, more preferably greater than about 30 N/15 mm and even more preferably greater than about 40 N/15 mm. The adhesive strength can be determined using a standard 180 degree pull test as described in ASTM D903-98.

### Second Encapsulant Layer 50

In another example of an encapsulant layer, a second encapsulant layer 50, is generally connectively located below the photovoltaic cell 20, although in some instances, it may directly contact the first encapsulant layer 40. It is contemplated that the second encapsulant layer 50 may serve a similar function as the first encapsulant layer, although it does not necessarily need to transmit electromagnetic radiation or light energy. Preferably, the second encapsulant layer 50 is configured to keep the plurality of conductive elements 60 in electrical contact with the conductive substrate layer 22. In the case that layer 50 is comprised of multiple layers, it is contemplated that the first layer formed proximal to the bottom surface of the cell (e.g. in contact with conductive substrate layer 22 and the conductive elements 60) has a higher melting temperature (Tₘ) than a second layer formed proximal to the first layer. It is contemplated that this configuration can provide the advantage that a processing temperature can be selected such that the first layer does not completely melt during heat treatment, but reaches sufficient temperature to cause adhesion of the first layer to the bottom of the cell. This configuration prevents loss of contact of the conductive elements with the conductive substrate layer 22 due to underflow of the encapsulant material between the conductive elements and the top conductive layer during heat treatment.

### EXAMPLES

In the following paragraphs, five (5) examples of the present invention and one (1) comparative example are presented. The following examples are provided to illustrate the invention but are not intended to limit the scope thereof.

### Examples Generally

For the purpose of these examples, CIGS type solar cells (50 mm×210 mm), on stainless steel substrate (e.g. conductive substrate layer 22), are obtained from Global Solar Inc. The cells are cut into smaller cells 50 mm (“L”)×25 mm (“W”). A Ni/Ag grid (e.g. collection structure 28) is applied to the top surface 26 of the cell onto the transparent conductive layer (ITO). In this case thirty (30) lines spanning across the larger cell dimension. The cells 20 are scribed down to the Mo layer (122) near the edge of the cells (e.g. from the outer edge, inboard about 1.0 to 2.0 mm). It is believed that use of such scribing is common in industry because of damage due from cutting the cell 20.

The symbols and short-hand notations herein are defined as:

V_{CC}=voltage−open circuit

I_{SC}=current−short circuit

FF=fill factor

Eff=efficiency

R_{S}=series resistance

Rₛₕ=shunt (parallel) resistance

R_{P}=Rₛₕ

Pₘₐₓ−Power (watts)

J_{SC}=current−short circuit per unit area (mA/cm²)

### Example 1

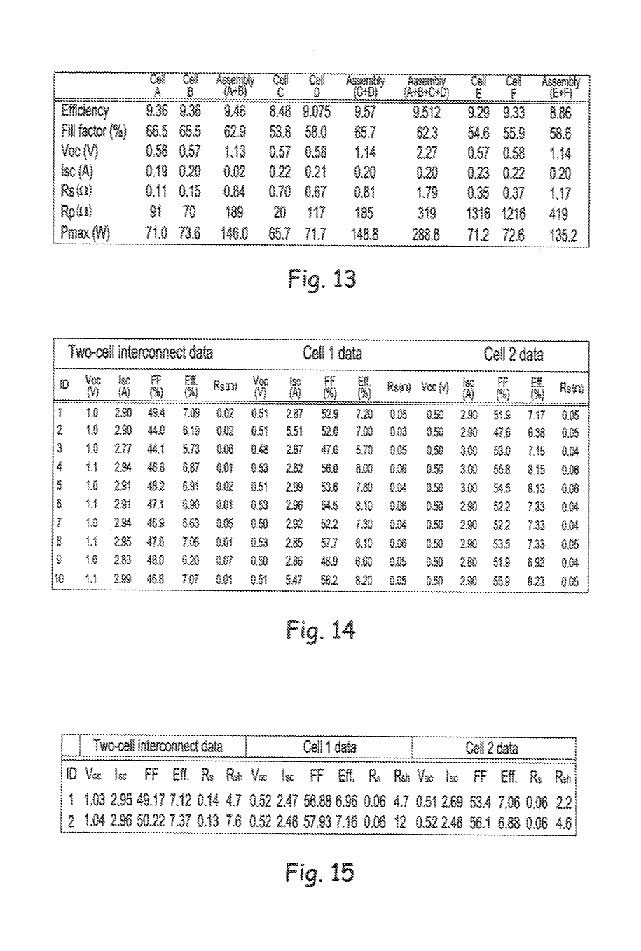

Two cells with the grids shown in FIG. 7 were treated on all four edges with polyimide (“kapton”®) tape (e.g. non-conductive layer portion 30) in such a manner that it was wrapped around the edge and covered the scribe section on the top of the cell. Three pieces of Ag-coated wire (30 AWG; e.g. conductive elements 60) was then applied to the surface of cell A and extended to the bottom of cell B, where the ends were attached locally to the stainless steel substrate using kapton tape (prior to the application of the encapsulants 40, 50). In a similar fashion, three pieces of 30 AWG Sn-coated wire were applied to the surface of cell A and extended beyond the cell edge. The wires were applied in a direction perpendicular to the direction of the fingers of the silver grid. No bonding material was used to attach the wire to the surface of the cells, (although a small piece of tape may be used to hold the elements 60 in-place until the lamination process can occur). The two cell assembly was then encapsulated between pieces of DNP PV-FS Z68 polyethylene sheet (e.g. encapsulants 40, 50—not shown) of 400 μm thickness, on the top and bottom in such a manner that the bottom stainless steel substrate of cell A and the wires that extended beyond cell B were available for electrical connection via clips. The DNP/solar cells/DNP assembly was then laminated at 150° C. CurrentA/oltage (I-V) characterization data for cell A and cell B individually, as well as the interconnected assembly are displayed in FIG. 13.

### Example 2

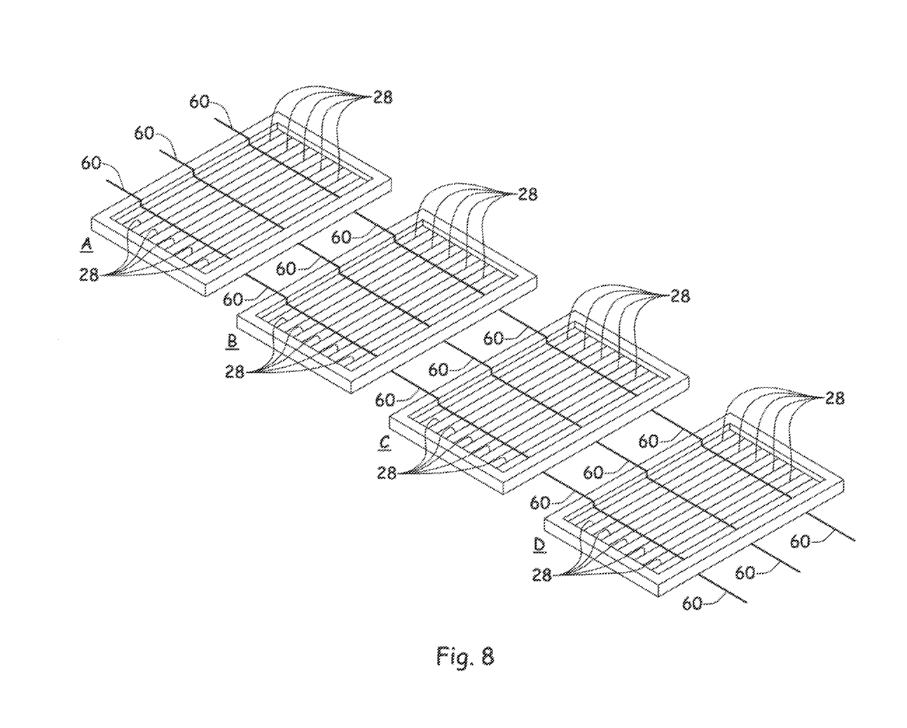

In this example, two (2) more cells 20 with grids were prepared and added to the two (2) cells of example one (1), as illustrated in FIG. 8. The cells will be referred to as cells C and D. The data for these cells and C and D connected together are summarized in FIG. 13. Cell assemblies A+B and C+D were then connected to each other using the same methodology to produce a four cell string.

A summary of the data for individual cells A, B, C and D as well as interconnected assemblies is shown in FIG. 13.

### Example 3

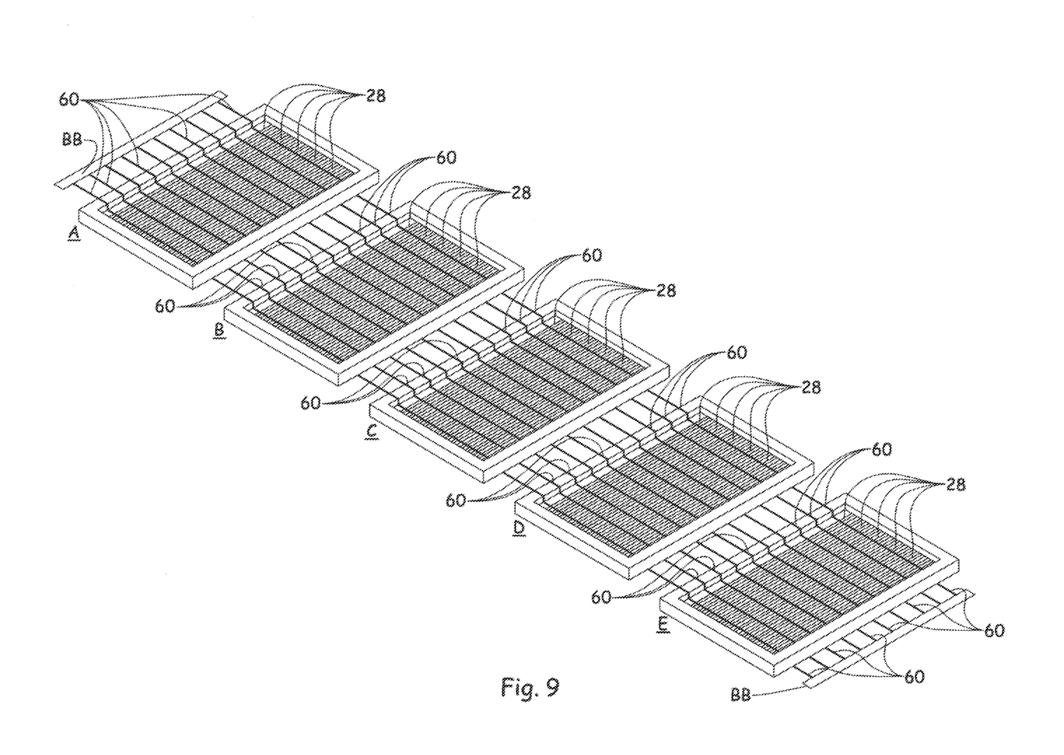

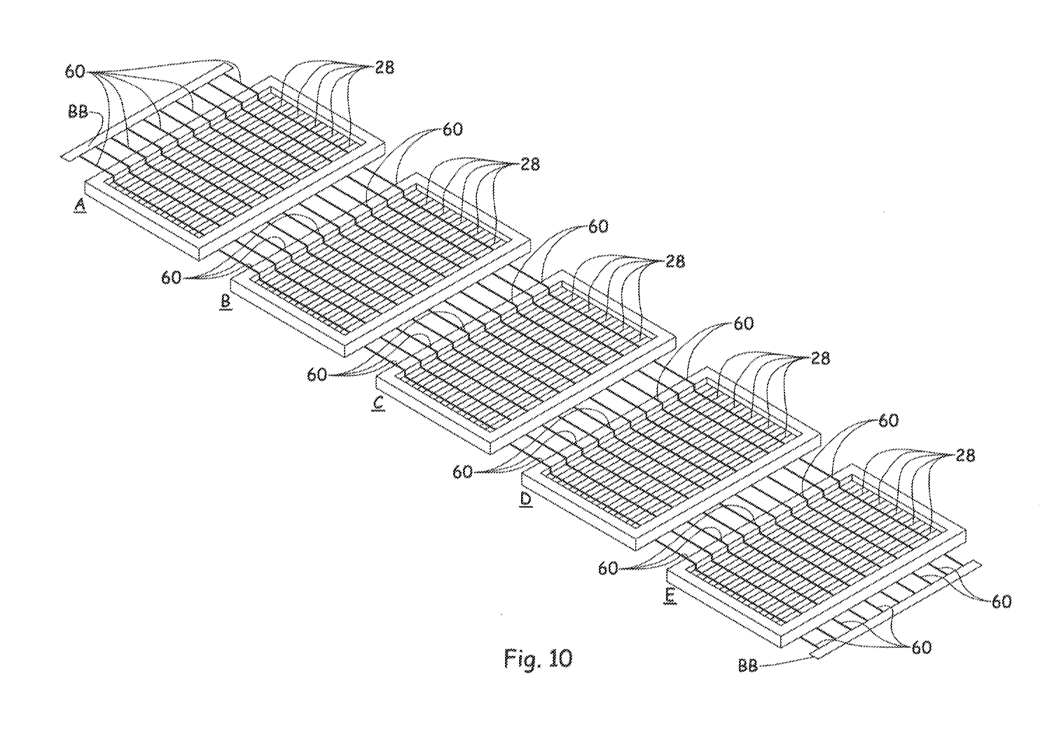

In this example, five (5) cells 20 with grids were prepared as in the previous examples. In this example, the cells 20 are assembled in top-to-bottom fashion using ten (10) Ag-plated Cu wires (30 AWG; e.g. conductive elements 60), as illustrated in FIG. 9. Again, no bonding material was used to attach the wire to the surface of the cells. The cell 20/elements 60 assemblies are encapsulated between pieces of DNP PV-FS Z68 polyethylene sheet (encapsulants 40, 50) on the top and bottom in such a manner that the wires extended beyond the edges of the end cells. The wires 60 were then attached to Sn-coated Cu bus bars (“BB”) via soldering using Sn/Pb solder. The DNP/solar cells/DNP assembly is then laminated at 110° C. I-V characterization data for the individual cells and the interconnected assembly are displayed in FIG. 14.

### Example 4

In this example, five (5) cells 20 with grids are prepared as in example 3. The cells 20 are assembled in top-to-bottom fashion using except that the 30 AWG Ag-plated Cu wire (elements 60) are substituted by 28 AWG Sn coated Cu wire (elements 60) as illustrated in FIG. 9. I-V characterization data for the individual cells and the interconnected assembly are displayed in FIG. 15.

### Example 5

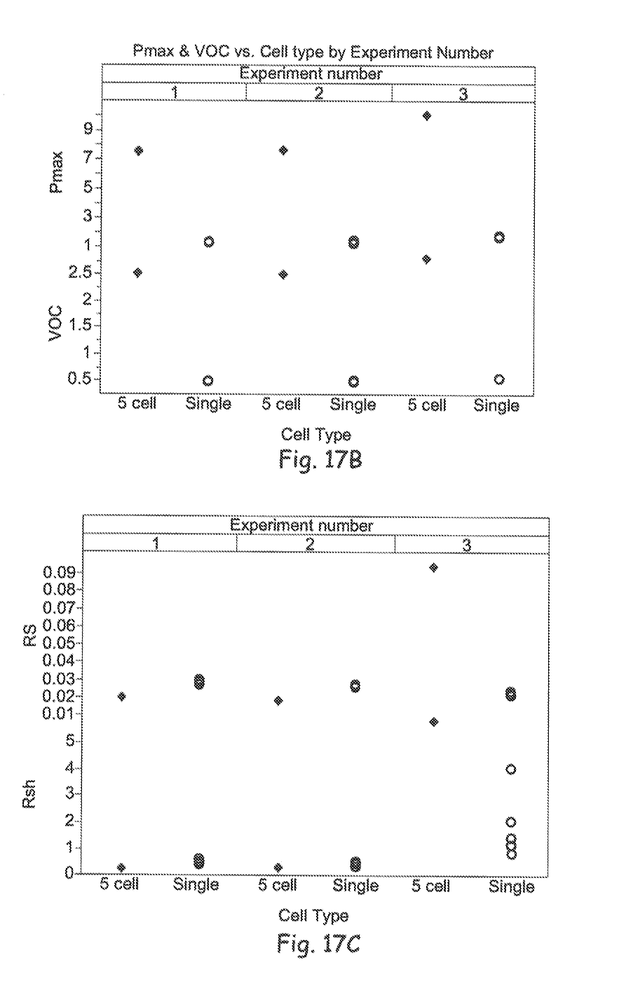

Three (3) five (5) cell assemblies are constructed in a similar fashion as examples 3 and 4. In this example, the a grid design has fourteen (14) lines spanning across the larger cell dimension are assembled in top-to-bottom fashion using eight (8) Sn-plated Cu wires, 28 AWG as illustrated in FIG. 11. I-V characterization data for the individual cells and the interconnected assembly are summarized in FIGS. 17A-C.

### Example 6 (Comparative Example)

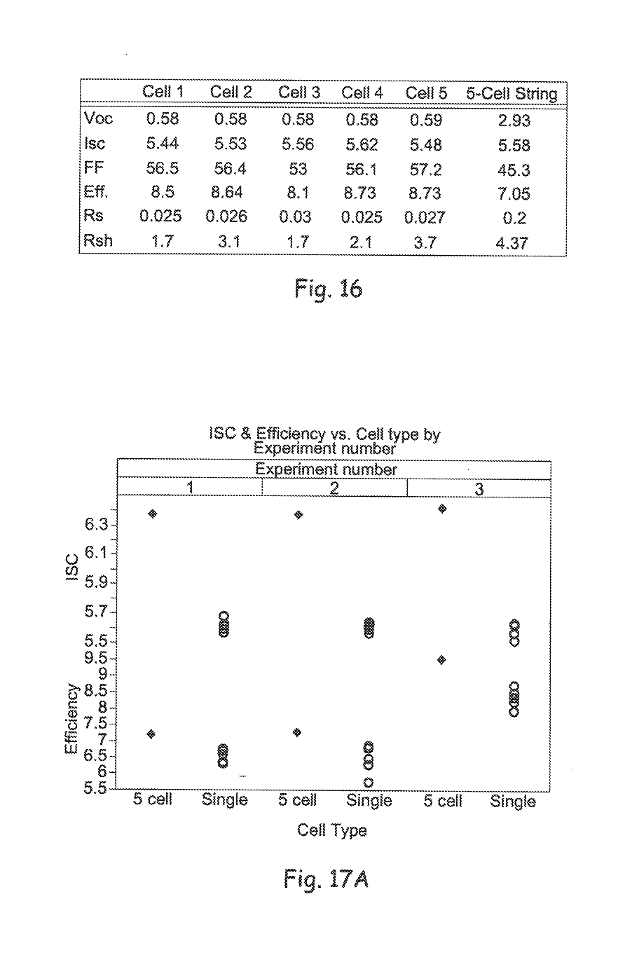

A five cell Global Solar assembly that is interconnected using conventional string and tab approach using conductive epoxy is characterized by I-V measurement. The string is then cut into five cells by cutting the ribbon between cells and I-V measurements are taken for each cell. The data summarized in FIG. 16 shows that the performance of the string can be significantly poorer than the individual cells, in contrast to the data obtained for the cells connected by the method described herein.

### Example 7 (Comparative Example)

Several five cell Global Solar assemblies interconnected using conventional string and tab approach using conductive epoxy were characterized by I-V measurement, then were cut into five cells by cutting the ribbon between cells as described in example 6. The 5 cells were re-assembled into strings using the approach described in Example 3 with eight 30 AWG I-V measurements are taken for each cell. The data summarized in FIG. 16 shows that the performance of the string can be significantly poorer than the individual cells. In contrast to the data obtained for the cells connected by the method described herein.

### Method

It is contemplated that the method of assembling the photovoltaic cells 20 into an assembly 10 is also inventive. It is contemplated that all the components described above are provided and the assembly method utilized to manufacture the assembly 10 include at least the following.

The first step may involve the application of the plurality of conductive elements 60 to the top surface 26 of each of the photovoltaic cells. Solar cells 20 can be provided in batches or stacks and manually or automatically provided to an unloading station. The solar cells 20 may alternatively be provided in the form of a continuous roll comprising a plurality of solar cells and separated from the roll just prior to assembly in a step referred to as singulation. The singulated solar cells 20 can be provided in bins that have been sorted by photovoltaic performance. The cells provided in the bins can be manually loaded individually by an operator, or more preferably an industrial robot can be used to pick individual cells from the bins and place in an inspection area. A vision system can then be used to guide an industrial robot in the precision pick-up and placement of the photovoltaic cells onto a flattop vacuum conveyor in the proper orientation. In one embodiment, the vision system includes a camera that takes a picture of the top surface of the cell, which conveys information regarding the exact orientation of the cell to the robot so that the robot can pick it up and placed it on the conveyor in a precisely positioned orientation.

The cells 20 can then be moved along the conveyor, during which time the non-conductive layer portion 30 can be applied near one or both of the edges of the cell either as a heat or UV-curable liquid dielectric, or in tape form. If the non-conductive layer is applied in tape form, it is preferred that the tape be of the type comprising adhesive on both sides, so that an adhesive surface is available to contact both the top surface 26 of the cell and the plurality of conductive elements 60.

As the cells with the non-conductive layer portion 30 are transported down the conveyor, the plurality of conductive elements 60 can be applied to the top surface 26 in a continuous form. The plurality of conductive elements can be secured to the top surfaces of the cell at both peripheral edges using the adhesive properties of the non-conductive layer portion. If the non-conductive layer portion is a double sided adhesive tape, the plurality of conductive elements can be help in place with the adhesive on the tape. If the non-conductive portions is a UV curable liquid dielectric, then the plurality of conductive elements can be partially embedded in the non-conductive layer portion. The liquid dielectric can then be cured to secure the conductive elements to the top surface of the cells at both peripheral edges.

The above process produces a continuous “string” of cells with a plurality of conductive elements contacting the top surface 26. The cells are separated by a sufficient gap to allow for the desired length of the conductive elements to extend beyond the trailing peripheral edge of each cell. This length is defined by the desired overlap “C_{A}” of the elements 60 on the conductive substrate layer 22 in the finished product. The plurality of conductive elements can then be cut at the leading edge of each solar cell to produce individual cells with a plurality of conductive elements contacting the top surface 26 and extending beyond the trailing edge of the solar cell. The cutting process can be carried out via a mechanical operation, such as using a nip, or by using a laser to cut the wires at the specified locations.

At the same time that the “strings” of cells are being fabricated, similar “strings” of buss or terminal bars can be fabricated in a similar fashion, wherein the plurality of conductive elements are attached to a plurality of terminal bars via welding or soldering. In a preferred embodiment, this process is carried out via laser welding. The conductive elements are cut to produce a single terminal bar with a plurality of conductive elements attached and extending in the trailing direction.

After the conductive elements are cut in the solar cell and terminal bar processes, the terminal bars with conductive elements attached can be transported via a pick and place mechanism into an interconnect area. The interconnect area may contain a fixture for holding the second encapsulant 50. The terminal bars can be secured in place. Then the cells with conductive elements extending beyond the trailing edge can be placed onto the second encapsulant layer such that the plurality of conductive elements that extends beyond the trailing edge of the terminal bar contacts the back of the first solar cell. A second cell can then be placed such that the plurality of conductive elements extending beyond the trailing edge of the first cell contact the back of the second cell This process is repeated until the desired number of cells are placed in the interconnected assembly. Then, a second terminal bar, without conductive elements attached is secured in place on the second encapsulant. The conductive elements that extend beyond the trailing edge of the last cell are attached to the second terminal bar using soldering or welding. In a preferred embodiment this process is carried out via laser welding.

Following completion of the interconnected assembly with terminal bars attached at opposing ends, the first encapsulant 40 can be placed over the fop of the interconnected assembly. The product with first encapsulant layer, solar cells, plurality of conductive elements and terminal bars is laminated, for example in a vacuum laminator, and thus the assembly 10 is complete.

Unless stated otherwise, dimensions and geometries of the various structures depicted herein are not intended to be restrictive of the invention, and other dimensions or geometries are possible. Plural structural components can be provided by a single integrated structure. Alternatively, a single integrated structure might be divided into separate plural components. In addition, while a feature of the present invention may have been described in the context of only one of the illustrated embodiments, such feature may be combined with one or more other features of other embodiments, for any given application. It will also be appreciated from the above that the fabrication of the unique structures herein and the operation thereof also constitute methods in accordance with the present invention.

The preferred embodiment of the present invention has been disclosed. A person of ordinary skill in the art would realize however, that certain modifications would come within the teachings of this invention. Therefore, the following claims should be studied to determine the true scope and content of the invention.

Any numerical values recited in the above application include all values from the lower value to the upper value in increments of one unit provided that there is a separation of at least 2 units between any lower value and any higher value. As an example, if it is stated that the amount of a component or a value of a process variable such as, for example, temperature, pressure, time and the like is, for example, from 1 to 90, preferably from 20 to 80, more preferably from 30 to 70, it is intended that values such as 15 to 85, 22 to 68, 43 to 51, 30 to 32 etc, are expressly enumerated in this specification. For values which are less than one, one unit is considered to be 0.0001, 0.001, 0.01 or 0.1 as appropriate. These are only examples of what is specifically intended and all possible combinations of numerical values between the lowest value and the highest value enumerated are to be considered to be expressly staled in this application in a similar manner.

Unless otherwise slated, all ranges include both endpoints and all numbers between the endpoints. The use of “about” or “approximately” in connection with a range applies to both ends of the range. Thus, “about 20 to 30” is intended to cover “about 20 to about 30”, inclusive of at least the specified endpoints.

The disclosures of all articles and references, including patent applications and publications, are incorporated by reference for all purposes.

The term “consisting essentially of” to describe a combination shall include the elements, ingredients, components or steps identified, and such other elements ingredients, components or steps that do not materially affect the basic and novel characteristics of the combination.

The use of the terms “comprising” or “including” describing combinations of elements, ingredients, components or steps herein also contemplates embodiments that consist essentially of the elements, ingredients, components or steps.

Plural elements, ingredients, components or steps can be provided by a single integrated element, ingredient, component or step. Alternatively, a single integrated element, ingredient, component or step might be divided into separate plural elements, ingredients, components or steps. The disclosure of “a” or “one” to describe an element, ingredient, component or step is not intended to foreclose additional elements, ingredients, components or steps. All references herein to elements or metals belonging to a certain Group refer to the Periodic Table of the Elements published and copyrighted by CRC Press, Inc., 1989. Any reference to the Group or Groups shall be to the Group or Groups as reflected in this Periodic Table of the Elements using the IUPAC system for numbering groups.

### LIST OF ELEMENT NUMBERS

photovoltaic cell assembly 10
photovoltaic cells 20
conductive substrate layer 22
photoactive layer 24
top surface 26
collection structure 28
non-conductive layer portion 30
first encapsulant layer 40
second encapsulant layer 50
conductive element 60
one end 62 of the conductive element 60
opposing end 64 of the conductive element 60
back contact layer 122
CuInGaSe(S) absorber layer 124
buffer layer 126
window layer 128
transparent conductive layer 130

1. A photovoltaic cell assembly comprising;
a plurality of photovoltaic cells comprising:
a photoactive portion sandwiched between;
a top electrically conductive structure on some regions: of atop surface of the photoactive portion leaving exposed top surface on other regions; and
an opposing conductive substrate layer;
wherein at least a portion of a peripheral edge portion of the cells include a non-conductive layer portion;
a plurality of conductive elements;
a first encapsulant layer in contact with the top electrically conductive structure and the exposed top surface of the photoactive portion; and
a second encapsulant layer in contact with the opposing conductive substrate layer;
wherein one end of the plurality of conductive elements contact the top electrically conductive structure and the exposed top surface-and an opposing end of the plurality of conductive elements contact the conductive substrate layer of an adjacent photovoltaic cell and both ends are held in contact to the cell layers by the respective encapsulant layer.

2. The photovoltaic cell assembly according to claim 1, wherein the top electrically conductive structure comprises a series of substantially parallel lines of a material with lower sheet resistance than the exposed top surface.

3. The photovoltaic cell assembly according to claim 2, wherein the series of substantially parallel lines is generally perpendicular to the direction of the plurality of conductive elements and the substantially parallel lines of the top electrically conductive structure are in contact with the conductive elements such that the conductive elements form an electrical bridge between the top electrically conductive structure and the the conductive substrate layer of an adjacent photovoltaic cell.

4. The photovoltaic assembly according to claim 1, wherein the conductive elements are connected to the photovoltaic cell elements without the use of conductive adhesive and/or solder.

5. The photovoltaic assembly according to claim 1, wherein the top electrically conductive structure occupies about 5 percent by weight or less of the total surface area of the photoactive portion associated with light capture.

6. The photovoltaic assembly according to claim 1, wherein the cross section width of the conductive elements is greater than the thickness of the first and second encapsulant layer.

7. The photovoltaic assembly according to claim 1, wherein a cross section width of the conductive elements is less than 0.5 mm and greater than 0.1 mm.

8. The photovoltaic assembly according to claim 1, wherein the conductive elements are connected to terminal bars at both ends of the assembly.

9. The photovoltaic assembly of claim 1, wherein the first encapsulate layer and the second encapsulant layer comprise multiple layers, wherein the first layer proximal to the top and bottom cell surfaces is a thermoplastic material with a higher melting point than the subsequent layers.

10. The photovoltaic assembly according to claim 1, wherein the top surface comprises a transparent conductive oxide.

11. The photovoltaic cell assembly of claim 1, wherein the photovoltaic cell assembly comprises at least five photovoltaic cells and at least three conductive elements in contact with each photovoltaic cell.

12. The photovoltaic cell assembly according to claim 1, wherein an overlap of the conductive elements on the conductive substrate layer is at least 2.0 mm in length.

13. The photovoltaic cell assembly of claim 1, wherein the non-conductive layer portion comprises a liquid dielectric that is cured via UV radiation.

14. The photovoltaic cell assembly of claim 1, wherein the first encapsulant layer, the second encapsulant layer, or both comprise at least a first and a second layer, wherein the first layer has a higher melting temperature (Tₘ) than the second layer.

15. The photovoltaic cell assembly according to claim 1, wherein an overlap of the conductive elements on the conductive substrate layer is about 2.0 mm to about 100 mm in length.

16. A method of forming a photovoltaic assembly comprising the steps of:
providing a first encapsulant layer and a second encapsulant layer;
providing a series of substantially parallel conductive elements;
providing a plurality of photovoltaic cells comprising a photoactive layer, an opposing conductive substrate layer and a top conductive layer comprising both a transparent conductive layer and a collection structure;
connecting the plurality of photovoltaic cells in top-to-bottom fashion
wherein the collection structure comprises a series of substantially parallel lines and a peripheral edge portion of the cells include a non-condunctive layer portion and one end of the plurality of conductive elements contact both the transparent conductive layer and the collection structure and an opposing end of the plurality of conductive elements contact the conductive substrate layer of an adjacent photovoltaic cell and both ends are held in contact to the cell layers by the respective encapsulant layer.
